(19) United States
(12) Patent Application Publication
(10) Pub. No.: US 2021/0184433 A1
(43) Pub. Date: Jun. 17, 2021

(54) Method of Fabricating Laser Devices Having Optical Modes Adjustable

(71) Applicant: AKAYLIGHT CORPORATION, Taipei (TW)

(72) Inventor: Ying-Jay Yang, Taipei (TW)

(21) Appl. No.: 16/904,769

(22) Filed: Jun. 18, 2020

(30) Foreign Application Priority Data
Dec. 13, 2019 (TW) 108145810

(51) Int. Cl. H01S 5/183

(52) U.S. Cl. CPC H01S 5/18394; H01S 5/18369

(57) ABSTRACT

A laser device is fabricated to obtain optical modes adjustable. A first distributed Bragg reflector (DBR), a light-emitting layer, a second DBR, and a third DBR are sequentially grown on a substrate through deposition, sputtering, or epitaxy. The third DBR comprises at least one dielectric layer. An aperture is selectively formed at center of the third DBR through etching. On using, the present invention practices the aperture at the dielectric layer on top of the laser device. The optical modes generated is adjustable by controlling the diameter of the aperture or the number of layers contained in the dielectric layer. The divergence angle is decreased to less than 15 degrees, so that the far-field emission has uniform intensity distribution and the emission distance is increased in optical fiber. Thus, a rational structure design, a simple assembly, and a low-cost high-volume manufacture are obtained for mass production.

### TECHNICAL FIELD OF THE INVENTION

The present invention relates to fabricating a laser device; more particularly, to practicing an aperture at a dielectric layer of a distributed Bragg reflector (DBR) on top of a laser device.

### DESCRIPTION OF THE RELATED ARTS

In recent years, artificial intelligence (AI) and car industry rapidly develop. An infrared-wavelength (700˜1600 nanometers) vertical-cavity surface-emitting laser (VCSEL) has the following features: (1) high speed; (2) high power-conversion efficiency (PCE); (3) coherency; (4) surface emission; (5) high-power matrix formation; and (6) easy wafer manufacture and package with low cost. Hence, a great amount of applications are found in sensing systems of AIs and auto-vehicles. But, general VCSELs use multimode emission, whose intensity distribution is uneven in far field as being low at center and high at surrounding. For improving the uneven intensity distribution of light emission in far field, a secondary optical lens needs to be added to the package, which results in increased cost, hardened manufacture, and lowered yield. Besides, a general VCSEL has an emitting angle of about 25 degrees (°). For sensor lights and luminous applications requiring small emitting angles (less than 15°), the secondary optical lens is still in need, which results in increased cost, hardened manufacture, and lowered yield, too. Hence, the prior arts do not fulfill all users' requests on actual use.

### SUMMARY OF THE INVENTION

The main purpose of the present invention is to practice an aperture at a dielectric layer of a distributed Bragg reflector (DBR) on top of a laser device with optical modes adjustable by controlling the diameter or area of the aperture and the number of layers contained in the dielectric layer.

Another purpose of the present invention is to provide a DBR with adjustable optical modes for obtaining uniform far-field luminous intensity and increased emission distance in optical fiber.

Another purpose of the present invention is to provide a DBR with adjustable optical modes having a decreased divergence angle (less than 15 degrees).

To achieve the above purposes, the present invention is a method of fabricating a laser device having optical modes adjustable, comprising steps of: (a) first step: growing a first distributed Bragg reflector (DBR) on a substrate through deposition, sputtering or epitaxy; (b) second step: growing a light-emitting layer (active layer) on the first DBR through deposition, sputtering or epitaxy; (c) third step: growing a second DBR on the light-emitting layer through deposition, sputtering or epitaxy; and (d) fourth step: growing at least one dielectric layer on the second DBR to form a third DBR through deposition, sputtering or epitaxy, and selectively forming an aperture through etching at center or at area surrounding center of the third DBR. Accordingly, a novel method of fabricating a laser device having optical modes adjustable is obtained.

### BRIEF DESCRIPTION OF THE DRAWINGS

The present invention will be better understood from the following detailed description of the preferred embodiment according to the present invention, taken in conjunction with the accompanying drawing, in which

FIG. 1 is the flow view showing the preferred embodiment according to the present invention; and

FIG. 2 is the view showing the laser device.

### DESCRIPTION OF THE PREFERRED EMBODIMENT

The following description of the preferred embodiment is provided to understand the features and the structures of the present invention.

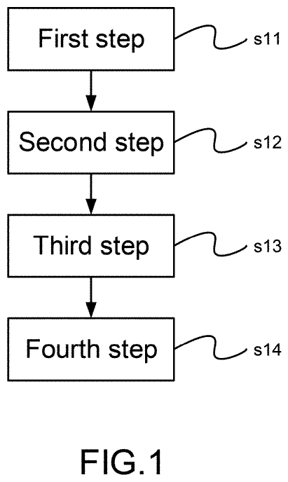

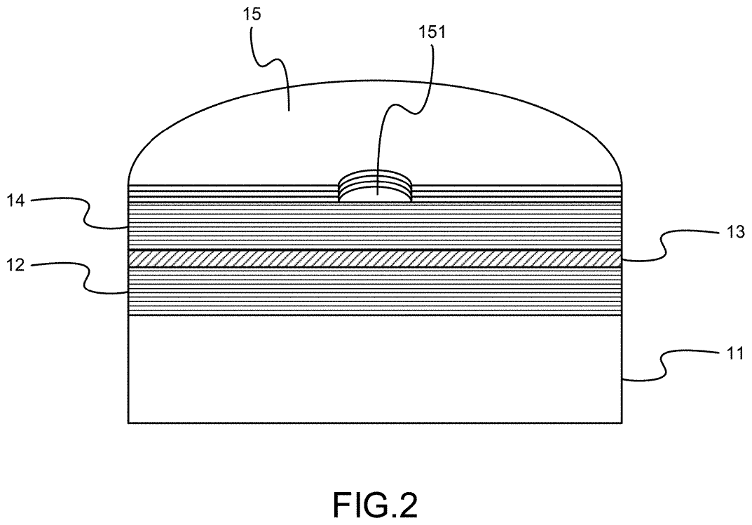

Please refer to FIG. 1 and FIG. 2, which are a flow view showing a preferred embodiment according to the present invention; and a view showing a laser device. As shown in the figure, the present invention is a method of fabricating a laser device having optical modes adjustable, comprising steps of:

(a) First step s11: A first distributed Bragg reflector (DBR) 12 is grown on a substrate 11 through deposition, sputtering or epitaxy, where the substrate 11 is a semiconductor substrate.

(b) Second step s12: A light-emitting layer (active layer) 13 is grown on the first DBR 12 through deposition, sputtering or epitaxy.

(c) Third step s13: A second DBR 14 is grown on the light-emitting layer 13 through deposition, sputtering or epitaxy.

(d) Fourth step s14: At least one dielectric layer is grown on the second DBR 14 to form a third DBR 15 through deposition, sputtering or epitaxy, and an aperture 151 is selectively formed through etching at center or at area surrounding center of the third DBR 15. Thus, a novel method of fabricating a laser device having optical modes adjustable is obtained.

In a state-of-use, the at least one dielectric layer of the third DBR 15 comprises 1˜20 layers; and the aperture 151 at center of the third DBR 15 has a diameter of 2˜15 micrometers. Therein, the dielectric layer of the third DBR 15 is made of silicon nitride (SiNₓ), silicon oxide (SiOₓ), aluminum oxide (AlOₓ), zinc oxide (ZnO), magnesium oxide (MgO), or any combination of the above.

On using, the present invention practices the aperture 151 at the dielectric layer of the third DBR 15 on top of the laser device, where optical modes generated by the laser device is adjustable by controlling the diameter or area of the aperture and the number of layers contained in the dielectric layer. Thereby, the divergence angle is changed to be decreased (to less than 15 degrees), so that the far-field light emission obtains uniform intensity distribution and the emission distance is increased in optical fiber. Besides, as compared to the heating-up process required in conventional zinc diffusion with result in material deterioration or some troubles happened during production with mass production being ruled out, the present invention can suppress the optical mode outside of the laser device through the aperture 151 and amend to improve the traditional uneven distribution of the far-field luminous intensity as being high at center and low at surrounding. Thus, the laser device obtains a rational design, a simple assembly, and a low-cost high-volume manufacture are obtained for mass production.

For a summary, the present invention is a method of fabricating a laser device having optical modes adjustable, where an aperture is practiced at a dielectric layer of a DBR on top of a laser device with the optical modes generated by the laser device adjustable by controlling the diameter or area of the aperture or the number of layers contained in the dielectric layer; and, thereby, the divergence angle is changed to be decreased (to less than 15 degrees) so that the far-field emission obtains uniform intensity distribution and the emission distance is increased in optical fiber.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A method of fabricating a laser device having optical modes adjustable, comprising steps of:
(a) first step: growing a first distributed Bragg reflector (DBR) on a substrate through a method selected from a group consisting of deposition, sputtering and epitaxy;
(b) second step: growing a light-emitting layer (active layer) on said first DBR through a method selected from a group consisting of deposition, sputtering and epitaxy;
(c) third step: growing a second DBR on said light-emitting layer through a method selected from a group consisting of deposition, sputtering and epitaxy; and
(d) fourth step: growing at least one dielectric layer on said second DBR to form a third DBR through a method selected from a group consisting of deposition, sputtering and epitaxy, and selectively forming an aperture through etching at a position selected from a group consisting of at center and at area surrounding center of said third DBR.

2. The method according to claim 1,
wherein said substrate is a semiconductor substrate.

3. The method according to claim 1,
wherein, in fourth step, said at least one dielectric layer of said third DBR comprises 1˜20 layers.

4. The method according to claim 1,
wherein, said at least one dielectric layer of said third DBR is made of a material selected from a group consisting of silicon nitride (SiNₓ), silicon oxide (SiOₓ), aluminum oxide (AlOₓ), zinc oxide (ZnO), magnesium oxide (MgO), and any combination of the above.

5. The method according to claim 1,
wherein, in fourth step, said aperture selectively formed through etching at a position selected from a group consisting of at center and at area surrounding center of said third DBR has a diameter of 2˜15 micrometers.
